(19) United States
(12) Patent Application Publication
(10) Pub. No.: US 2026/0175186 A1
(43) Pub. Date: Jun. 25, 2026

(54) SEMICONDUCTOR PROCESSING SYSTEM AND METHOD OF OPERATING THE SAME

(71) Applicant: Tokyo Electron Limited, Tokyo (JP)

(72) Inventors: Fu Chieh HSU, Hsinchu City (TW); Chun Hung HUNG, Hsinchu City (TW); Cheng Hsiung LEE, Hsinchu City (TW); Chi Ming KUO, Hsinchu City (TW); Chun Hung HUNG, Hsinchu City (TW)

(21) Appl. No.: 19/415,156

(22) Filed: Dec. 10, 2025

Related U.S. Application Data
(60) Provisional application No. 63/738,021, filed on Dec. 23, 2024.

(51) Int. Cl. B01F 35/91; B01F 23/10; B01F 35/221; B01F 35/71; B01F 35/90; B01F 101/58; H10P 72/00

(52) U.S. Cl. CPC B01F 35/91; B01F 23/10; B01F 35/2213; B01F 35/712; B01F 35/71805; H10P 72/0402; B01F 2035/98; B01F 2101/58; B01F 2215/0468; B01F 2215/0472

(57) ABSTRACT

A semiconductor processing system includes a process reaction chamber, a process gas exhaust pipeline, and a cooling gas source. The process gas exhaust pipeline is connected to the process reaction chamber and configured to expel a process gas from the process reaction chamber. The cooling gas source is connected to the process gas exhaust pipeline through a cryogenic gas delivery pipeline and configured to supply a cooling gas into the process gas exhaust pipeline via the cryogenic gas pipeline.

### CROSS-REFERENCE TO RELATED APPLICATIONS

This application claims priority to and the benefit of U.S. Provisional Patent Application No. 63/738,021 filed on Dec. 23, 2024. The entirety of the above-mentioned patent application is hereby incorporated by reference herein.

### TECHNICAL FIELD

The present disclosure relates to semiconductor processing systems and methods of operating the same, in particular, semiconductor high-temperature process gas exhaust systems and methods of operating the same.

### BACKGROUND

Process gases exhaust systems for process gases play a crucial role in semiconductor processing. Traditional semiconductor process gas exhaust systems generally comprise several main components, including the process gas source, the process gas reaction chamber, and the process gas exhaust device. The process gas source is responsible for providing specific gases, which are introduced into the reaction chamber to undergo chemical reactions. The reaction chamber is an enclosed space designed to facilitate chemical reactions between gases, usually equipped with heating devices to maintain the required reaction temperature. Once the reaction is accomplished, the resulting gases need to be safely discharged from the exhaust system. Therefore, the exhaust system typically includes components such as pipelines and valves to ensure that process gases can be effectively discharged and treated.

Traditional gas reaction exhaust systems encounter several operational challenges. The gases produced after the reaction are typically at high temperatures, which demands specific materials and designs for the exhaust system. If these high-temperature gases are not adequately cooled, they can damage the exhaust system and reduce its lifespan. Furthermore, directly releasing high-temperature gases can harm the environment and increase the system's operational risks.

Thus, traditional exhaust systems for process gases often require a cooling mechanism to reduce the gas temperature before discharging the gases. This requirement complicates the system and extends the overall reaction time, as the process gas reaction chamber must wait for the previous gases to cool before accommodating new ones. Additionally, the cooling process in traditional systems is often inefficient, reducing overall process efficiency and increasing energy consumption, which raises operational costs.

In light of the above, there is an urgent need for improvements in process gas reaction exhaust systems.

### SUMMARY

In accordance with an embodiment of the present disclosure, a semiconductor processing system comprises a process reaction chamber, a process gas exhaust pipeline, and a cooling gas source. The process gas exhaust pipeline is connected to the process reaction chamber and configured to expel a process gas from the process reaction chamber. The cooling gas source is connected to the process gas exhaust pipeline through a cryogenic gas delivery pipeline and configured to supply a cooling gas into the process gas exhaust pipeline via the cryogenic gas delivery pipeline.

In accordance with an embodiment of the present disclosure, a semiconductor processing system comprises a process reaction chamber, a process gas exhaust pipeline, and a cooling gas source. The process reaction chamber comprises an inner chamber and an outer chamber at least partially enclosing the inner chamber. The process gas exhaust pipeline is configured to expel a process gas that undergoes high-temperature and high-pressure reaction in the inner chamber. The cooling gas source is configured to supply a cooling gas to the process gas exhaust pipeline via a cryogenic gas delivery pipeline, thereby allowing the cooling gas to mix with the process gas expelled from the inner chamber.

In accordance with an embodiment of the present disclosure, a method of operating semiconductor processing system comprises discharging a process gas from a process reaction chamber into a process gas exhaust pipeline; supplying a cooling gas into the process gas exhaust pipeline, wherein a temperature of the cooling gas is lower than a temperature of the process gas and wherein a pressure of the cooling gas is greater than a pressure of the process gas; and; and mixing the process gas with the cooling gas in the process gas exhaust pipeline.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

The present disclosure as well as a preferred mode of use, further objectives, and advantages thereof will be best understood by referring to the following detailed description of illustrative embodiments in conjunction with the accompanying drawings, wherein:

FIG. 1 is a schematic diagram illustrating a semiconductor processing system according to an embodiment of the present disclosure;

FIG. 2 is a schematic diagram illustrating a semiconductor processing system according to an embodiment of the present disclosure;

FIG. 3 is a flow chart illustrating a method of operating a semiconductor processing system according to an embodiment of the present disclosure;

FIG. 4 is a diagram illustrating the pressure relief rate when different configurations are utilized according to an embodiment of the present disclosure;

FIG. 5 is a diagram illustrating the cooling time required for the process gas when different configurations are utilized according to an embodiment of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

The semiconductor process gas exhaust systems typically include a reaction chamber for the process gases and an exhaust device. Since the process gases undergo high-temperature reactions, which elevate them to high temperatures before being exhausted, the exhaust system often utilizes a cooling mechanism to reduce the gas temperature. For example, the reaction chamber may comprise an inner chamber and an outer chamber. This configuration allows for the reduction of gas temperature in the outer chamber, thereby cooling the high-temperature process gases within the inner chamber, which is typically constructed from non-metallic materials (e.g., quartz). Another approach involves connecting the high-temperature zone of the inner chamber with the low-temperature zone of the outer chamber. This connection reduces the gas temperature in the outer chamber, cooling the high-temperature process gases in the inner chamber, while also mixing gases in the low-pressure zone to decrease gas concentration. By way of example, a valve can be installed between the high-temperature and low-temperature zones of the outer chamber. When opened, this valve allows gas to be discharged and mixed with gas in subsequent pipelines, thereby reducing the gases concentration.

However, cooling the high-temperature process gases in the inner chamber through thermal conduction with the low-temperature zone of the outer chamber may be inefficient. This is because the inner chamber is usually made of non-metallic materials with low thermal conductivity, preventing rapid cooling of the high-temperature gases by the outer chamber's low-temperature gases. Moreover, in the configuration where a valve is set between the high-temperature and low-temperature zones of the outer chamber, the process gases may not be effectively cooled before passing through the valve, which can easily lead to valve damage and shorten its lifespan. In particular, when the process gases maintain a high temperature while passing through the valve, the sealing performance of the valve may deteriorate, leading to increased leakage risk, higher maintenance costs, and shortened equipment lifetime. Furthermore, the prolonged cooling process can extend the overall process cycle time, adversely affecting the productivity and operational efficiency of the semiconductor manufacturing process.

Embodiments of the present discourse provide enhanced semiconductor process gas exhaust systems and methods of operating the same, wherein the temperature of the process gas can be rapidly reduced, and the lifespan of the gas exhaust valve can be effectively extended. The characteristics, subject matter, advantages, and effects of the present disclosure are detailed hereinafter by reference to embodiments of the present disclosure and the accompanying drawings. It is understood that the drawings referred to in the following description are intended solely for illustrative purposes and do not necessarily depict the actual proportions and precise arrangement of the embodiments. Therefore, the proportions and arrangements shown in the drawings should not be construed as limiting or restricting the scope of the present disclosure.

Through the improvements disclosed herein, the present invention can achieve faster cooling of process gases, minimize the thermal burden on exhaust valves, and enhance the overall stability, safety, and efficiency of semiconductor manufacturing systems.

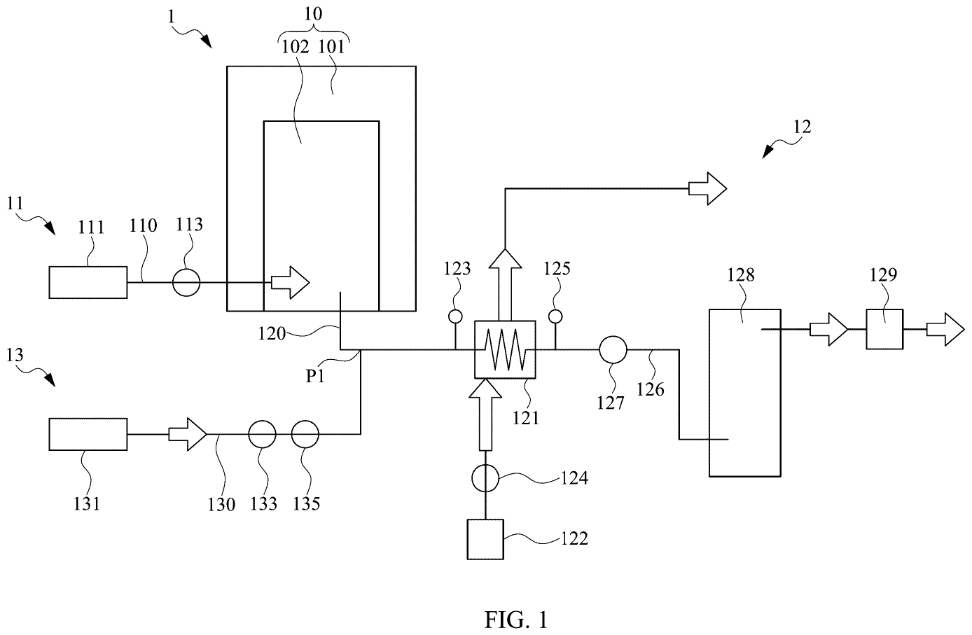

FIG. 1 is a schematic diagram showing a semiconductor processing system 1 of the present disclosure. As shown in FIG. 1, the semiconductor processing system 1 may include a process reaction chamber 10, a process gas supply assembly 11, a process gas discharge assembly 12 and a cooling gas supply assembly 13. The process reaction chamber 10 may include an outer chamber 101 and an inner chamber 102. In some embodiments of the present disclosure, the inner chamber 102 includes a high-pressure heat treatment vessel used for conducting high-temperature and high-pressure process reactions, primarily serving to contain process gases and facilitate such reactions. In some embodiments of the present disclosure, the outer chamber 101 encapsulates the inner chamber 102.

The process gas supply assembly 11 is configured to supply a process gas into the inner chamber 102 of the process reaction chamber 10. As shown in FIG. 1, the process gas supply assembly 11 may include a process gas source 111, a booster element 113 and a process gas supply pipeline 110. The process gas supply pipeline 110 is configured to connect the process gas source 111 to the inner chamber 102 of the process reaction chamber 10. That is, the inner chamber 102 may be in fluid communication with the process gas source 111. Moreover, the booster element 113 may be connected to the process gas supply pipeline 110 and positioned downstream of the process gas source 111.

The process gas source 111 is configured to supply the process gas into the inner chamber 102 of the process reaction chamber 10 through the process gas supply pipeline 110. Moreover, the process gas supplied from the process gas source 111 may be pressurized by the booster element 113, before being delivered through the process gas supply pipeline 110 into the inner chamber 102. The process gas is utilized for conducting high-pressure and high-temperature reactions within the inner chamber 102.

The process gas discharge assembly 12 is configured to expel the process gas from the inner chamber 102 of the process reaction chamber 10. Referring to FIG. 1, the process gas discharge assembly 12 may include a process gas exhaust pipeline 120 connected to the inner chamber 102, thereby allowing the process gas to flow from the inner chamber 102 into the process gas exhaust pipeline 120. The process gas flowing from the inner chamber 102 into the process gas exhaust pipeline 120 may include process gas having a temperature of at least 850° C. and a pressure of approximately 200 Pa.

The process gas discharge assembly 12 may include a cooler 121 connected to the process gas exhaust pipeline 120 and configured to cool the process gas flowing therethrough. In some embodiments of the present disclosure, the cooler 121 comprises a coil heat exchanger configured to facilitate heat exchange between the process gas and an inert refrigerant. The cooler 121 may be fluidly connected to an inert refrigerant source 122, thereby allowing the inert refrigerant to flow from the inert refrigerant source 122 into the cooler 121. A switching element 124 may be disposed between the inert refrigerant source 122 and the cooler 121, and may be configured to control the introduction of the inert refrigerant into the cooler 121.

Further, the inert refrigerant introduced into the cooler 121 may absorb heat from the process gas passing through the cooler 121, and subsequently exit the cooler 121 after the heat exchange is completed. Accordingly, the cooler 121 may be equipped with a process gas inlet and outlet, as well as an inert refrigerant inlet and outlet, to respectively accommodate the flow of the process gas and the inert refrigerant.

In some embodiments of the present disclosure, the inert refrigerant may comprise, but is not limited to, gases such as nitrogen (N₂), argon (Ar), helium (He), carbon dioxide (CO₂), or mixtures thereof, or may be a liquid coolant compatible with the process conditions.

Additionally, the process gas discharge assembly 12 may include temperature measuring elements 123 and 125 connected to the process gas exhaust pipeline 120 and adjacent to the cooler 121. The temperature measuring element 123 may be located upstream of the cooler 121 and the temperature measuring element may be located downstream of the cooler 121. The user can utilize a temperature measuring elements 123 and 125 to measure the temperature changes of the process gas as it flows through the cooler 121.

Referring to FIG. 1, the process gas discharge assembly 12 may include a pressure control element 127. The pressure control element 127 may be connected to the process gas exhaust pipeline 120 and located downstream of the cooler 121. The pressure control element 127 is configured to reduce the pressure of the process gas that has been cooled by the cooler 121. In some embodiments of the present disclosure, the pressure control element 127 may comprise a gas exhaust valve configured to discharge the gas at a controlled rate.

The process gas discharge assembly 12 may include a process gas low pressure buffer vessel 128 connected to the pressure control element 127 through a process gas low pressure exhaust pipe 126. The process gas low pressure buffer vessel 128 may be configured to temporarily store the process gas after the pressure reduction and to regulate the subsequent discharge flow.

In some embodiments, the buffer vessel 128 may serve to stabilize fluctuations in gas flow rate and pressure, thereby protecting downstream exhaust systems from pressure surges and facilitating a more uniform exhaust operation.

Additionally, the process gas low pressure buffer vessel 128 may include internal features such as a gas inlet, a gas outlet, and optionally, pressure sensors or safety valves to monitor and control internal conditions.

The cooling gas supply assembly 13 may be connected to the process gas exhaust pipeline 120 and configured to supply a cooling gas into the process gas exhaust pipeline 120. In the present disclosure, the cooling gas may be high pressure and low temperature gas or high pressure and ambient temperature gas. In some embodiments of the present disclosure, the cooling gas may have a temperature ranging from approximately room temperature (e.g., about 24° C.) to about 850° C. In some embodiments of the present disclosure, the cooling gas may have a pressure greater than or equal to 200 Pa.

In some embodiments of the present disclosure, the temperature of the cooling gas falls within any of the following ranges: about 24° C. to about 45° C.; about 24° C. to about 65° C.; about 24° C. to about 85° C.; about 24° C. to about 110° C.; about 24° C. to about 130° C.; about 24° C. to about 150° C.; about 24° C. to about 170° C.; about 24° C. to about 190° C.; about 24° C. to about 210° C.; about 24° C. to about 230° C.; about 24° C. to about 250° C.; about 24° C. to about 270° C.; about 24° C. to about 290° C.; about 24° C. to about 310° C.; about 24° C. to about 330° C.; about 24° C. to about 350° C.; about 24° C. to about 370° C.; about 24° C. to about 390° C.; about 24° C. to about 410° C.; about 24° C. to about 430° C.; about 24° C. to about 455° C.; about 24° C. to about 480° C.; about 24° C. to about 500° C.; about 24° C. to about 520° C.; about 24° C. to about 540° C.; about 24° C. to about 560° C.; about 24° C. to about 580° C.; about 24° C. to about 600° C.; about 24° C. to about 620° C.; about 24° C. to about 640° C.; about 24° C. to about 660° C.; about 24° C. to about 680° C.; about 24° C. to about 700° C.; about 24° C. to about 720° C.; about 24° C. to about 740° C.; about 24° C. to about 760° C.; about 24° C. to about 780° C.; about 24° C. to about 800° C.; about 24° C. to about 825° C.; or about 24° C. to about 850° C.

The cooling gas supply assembly 13 may include a cooling gas source 131 configured to supply the cooling gas and a cryogenic gas delivery pipeline 130 configured to connect the cooling gas source 131 to the process gas exhaust pipeline 120. That is, cooling gas may flow from the cooling gas source 131 to the process gas exhaust pipeline 120 through the cryogenic gas delivery pipeline 130. When the cooling gas flows into the process gas exhaust pipeline 120, the temperature of the process gas within the process gas exhaust pipeline 120 is reduced. In some embodiments of the present disclosure, the joint P1 of the cryogenic gas delivery pipeline 130 and the process gas exhaust pipeline 120 is located upstream of the cooler 121. Thus, if the cooling gas is supplied to the process gas exhaust pipeline 120, the process gas can be cooled before passing through the cooler 121.

Moreover, the cooling gas supply assembly 13 may include a gas delivery pipe switching element 133 and a one-way valve 135 connected to the cryogenic gas delivery pipeline 130, wherein the gas delivery pipe switching element 133 is located downstream of the cooling gas source 131 and the one-way valve 135 is located downstream of the gas delivery pipe switching element 133. The gas delivery pipe switching element 133 may be configured to selectively control the opening and closing of the cryogenic gas delivery pipeline 130, thereby regulating whether the cooling gas is introduced into the process gas exhaust pipeline 120. The one-way valve 135 may be configured to allow the cooling gas to flow only from the cooling gas source 131 toward the process gas exhaust pipeline 120, and to prevent the process gas or any backflow gas from the process gas exhaust pipeline 120 from flowing back into the cryogenic gas delivery pipeline 130. Through this configuration, reverse contamination of the cooling gas source 131 and the cryogenic gas delivery pipeline 130 can be effectively avoided, thereby ensuring the purity of the cooling gas and maintaining the stability and safety of the overall system operation.

After the high-pressure, high-temperature process reaction is performed in the inner chamber 102, the process gas may be discharged through the process gas exhaust pipeline 120. As the gas flows along the process gas exhaust pipeline 120, it undergoes a cooling process designed to lower its temperature. The process gas is first mixed with a cooling gas (the high pressure and low temperature gas or high pressure and ambient temperature gas) supplied from the cooling gas supply assembly 13 and subsequently flows through the cooler 121 for further temperature reduction. After cooling, the process gas flows through the pressure control element 127. The process gas is depressurized by the pressure control element 127, where its pressure is reduced. Finally, the cooled and depressurized process gas is discharged into the process gas low pressure buffer vessel 128 for safe handling and storage.

The cooling gas, supplied from the cooling gas source 131, is delivered to the process gas exhaust pipeline 120 through the cryogenic gas delivery pipeline 130. The joint P1 of the cryogenic gas delivery pipeline 130 and the process gas exhaust pipeline 120 is located upstream of the cooler 121 and the pressure control element 127. At this point, the cooling gas mixes directly with the high-temperature process gas, initiating an immediate reduction in its temperature. This fluid mixing ensures rapid and efficient heat transfer, significantly lowering the process gas temperature before it reaches the cooler 121 for secondary cooling. In some embodiments of the present disclosure, the joint P1 between the cryogenic gas delivery pipeline 130 and the process gas exhaust pipeline 120 may be positioned proximate to the process reaction chamber 10. In some embodiments of the present disclosure, the distance between the joint P1 and the process reaction chamber 10 may be shorter than the distance between the joint P1 and the cooler 121. In some embodiments of the present disclosure, the distance between the joint P1 and the process reaction chamber 10 may be less than or equal to half of the distance between the joint P1 and the cooler 121. In some embodiments of the present disclosure, the distance between the joint P1 and the process reaction chamber 10 may be less than or equal to one-fourth of the distance between the joint P1 and the cooler 121. In some embodiments of the present disclosure, the distance between the joint P1 and the process reaction chamber 10 may be less than or equal to one-eighth of the distance between the joint P1 and the cooler 121. By such an arrangement, the process gas can be mixed with the cooling gas and cooled as quickly as possible immediately after being discharged from the process reaction chamber 10.

The cooling gas may include a variety of gases, such as hydrogen (H₂), deuterium (D₂), carbon dioxide (CO₂), nitrogen (N₂), helium (He), argon (Ar), or a combination of these gases. Inert gases may be suitable as they can dilute the process gas during mixing, thereby reducing its concentration and minimizing potential hazards during the exhaust process.

In embodiments where the cooling gas and the process gas are of the same type, mixing the cooling gas with the process gas does not introduce contamination from different gas species. Consequently, the process gas can be subjected to purification and subsequently recycled and reused after the completion of the process. Using a cooling gas of the same type as the process gas not only prevents contamination but also significantly improves cost efficiency and enhances overall economic benefits. This advantage becomes particularly notable when the process gas is a high-value or expensive material, as recycling and reuse can substantially reduce material consumption and operational costs.

In some embodiments of the present disclosure, a purifier 129 may be connected to the process gas low pressure buffer vessel 128 and disposed downstream of the process gas low pressure buffer vessel 128. The purifier 129 may be configured to receive the gas mixture discharged from the buffer vessel 128. When the cooling gas and the process gas are of the same type, such as when both comprise the same chemical species, the mixed gas discharged from the process gas low pressure buffer vessel 128 may be introduced into the purifier for purification. After purification, the gas may be recovered and reused in subsequent processing steps, thereby improving resource utilization efficiency and reducing overall operational costs.

The pressure of the cooling gas from the cooling gas source 131 is equal to or higher than the pressure of the process gas. In some embodiments of the present disclosure, the cooling gas may have a pressure greater than or equal to 200 Pa. This ensures that the entire system operates normally and prevents backflow. In some embodiments, the gas delivery pipe switching element 133 is configured to control the flow of the cooling gas. Additionally, the one-way valve 135 is configured to prevent backflow of the cooling gas, maintain the stability of the system pressure, and ensure that the cooling gas flows in the correct direction.

In the embodiment illustrated in FIG. 1, the cooler 121 is positioned upstream of the pressure control element 127 and downstream of the joint P1. In other words, the high-pressure, high-temperature process gas first mixes with the cooling gas after being discharged from the high-pressure heat treatment vessel (inner chamber 102), and then undergoes secondary cooling via the cooler 121 before passing through the pressure control element 127. After these steps, the process gas enters the gas low pressure buffer vessel 128.

In the embodiment illustrated in FIG. 1, the process gas, after being mixed with the cooling gas, flows along the process gas exhaust pipeline 120 into the process gas inlet of the cooler 121 and is discharged from the process gas outlet of the cooler 121. Additionally, the cooler 121 is arranged with an inert refrigerant inlet and an inert refrigerant outlet, wherein the inert refrigerant inlet is connected to the inert refrigerant source 122. The inert refrigerant may flow from the inert refrigerant source 122 into the inert refrigerant inlet of the cooler 121. It may exchange heat with the process gas flowing through the cooler 121, and then exits through the inert refrigerant outlet, thereby cooling down the process gas.

In the present disclosure, the inert refrigerant may be in gaseous or liquid form, and its flow is regulated by a refrigerant switching element 124. The refrigerant switching element 124 may include a flow valve, which is used to control the flow rate and volume of the refrigerant. This enables precise control of the refrigerant supply, ensuring optimal cooling efficiency.

The temperature measuring elements 123 and 125 are configured to sense and monitor the temperature of the process gas as it flows into and out of the cooler 121, thus ensuring that the process gas is cooled to the required temperature range.

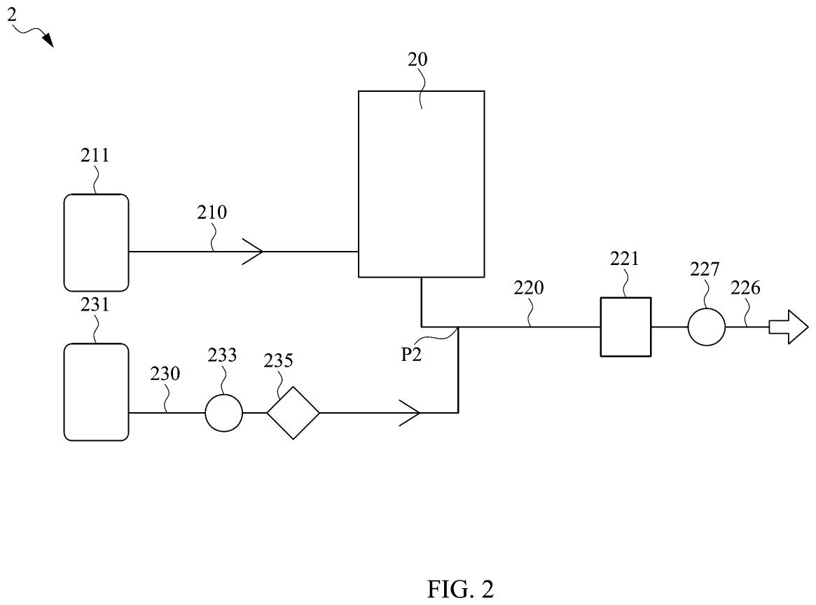

FIG. 2 is a schematic diagram showing one embodiment of the semiconductor processing system 2 of the present disclosure. As shown in FIG. 2, the semiconductor processing system 2 may include a process reaction chamber 20. In some embodiments of the present disclosure, the process reaction chamber 20 is the same as, or similar to, the process reaction chamber 10 shown in FIG. 1. That is, the process reaction chamber 20 may include a high-pressure heat treatment vessel used for conducting high-temperature and high-pressure process reactions, primarily serving to contain process gases and facilitate such reactions.

The semiconductor processing system 2 may include a process gas source 211 and a process gas supply pipeline 210. The process gas supply pipeline 210 is configured to connect the process gas source 211 to the process reaction chamber 20. That is, the process reaction chamber 20 may be in fluid communication with the process gas source 211.

The process gas source 211 is configured to supply the process gas into the process reaction chamber 20 through the process gas supply pipeline 210. Moreover, the process gas supplied from the process gas source 211 may be pressurized before being delivered into the process reaction chamber 20. The process gas is utilized for conducting high-pressure and high-temperature reactions within the process reaction chamber 20.

Referring to FIG. 2, the semiconductor processing system 2 may include a process gas exhaust pipeline 220 connected to the process reaction chamber 20, thereby allowing the process gas to flow from the process reaction chamber 20 into the process gas exhaust pipeline 220. The process gas flowing from the process reaction chamber 20 into the gas exhaust pipeline 220 may include process gas having a temperature of at least 850° C. and a pressure of approximately 200 Pa. In some embodiments, the temperature of the cooling gas falls within any of the ranges disclosed above.

Moreover, a cooler 221 is connected to the process gas exhaust pipeline 220 and configured to cool the process gas as it flows through. In some embodiments of the present disclosure, the cooler 221 includes a coil heat exchanger. In some embodiments of the present disclosure, the cooler 221 is identical or similar to the cooler 121 as shown in FIG. 1.

Referring to FIG. 2, the semiconductor processing system 2 may include a pressure control element 227. The pressure control element 227 may be connected to the process gas exhaust pipeline 220 and located downstream of the cooler 221. The pressure control element 227 is configured to reduce the pressure of the process gas that has been cooled by the cooler 221. In some embodiments of the present disclosure, the pressure control element 227 is identical or similar to the pressure control element 127 as shown in FIG. 1.

Moreover, a process gas low pressure exhaust pipe 226 is connected to the pressure control element 227 and configured to deliver the process gas from the process gas exhaust pipeline 220. Once the process gas is depressurized by the pressure control element 227, it can flow through the process gas exhaust pipeline 220 and be discharged from the semiconductor processing system 2.

As shown FIG. 2, the semiconductor processing system 2 may include a cooling gas source 231 configured to supply the cooling gas (high pressure and low temperature gas or high pressure and ambient temperature gas) and a cryogenic gas delivery pipeline 230 configured to connect the cooling gas source 231 to the process gas exhaust pipeline 220. That is, the cooling gas may flow from the cooling gas source 231 to the process gas exhaust pipeline 220 through the cryogenic gas delivery pipeline 230. In some embodiments of the present disclosure, the cooling gas may have a temperature ranging from approximately room temperature to about 850° C. In some embodiments, the temperature of the cooling gas falls within any of the ranges disclosed above. In some embodiments of the present disclosure, the cooling gas may have a pressure greater than or equal to 200 Pa.

When the cooling gas flows into the process gas exhaust pipeline 220, the temperature of the process gas within the process gas exhaust pipeline 220 is reduced. In some embodiments of the present disclosure, the joint P2 of the cryogenic gas delivery pipeline 230 and the process gas exhaust pipeline 220 is located upstream of the cooler 221. Thus, if the high cooling gas is supplied to the process gas exhaust pipeline 220, the process gas can be cooled before passing through the cooler 221.

In some embodiments of the present disclosure, the joint P2 between the cryogenic gas delivery pipeline 230 and the process gas exhaust pipeline 220 may be positioned proximate to the process reaction chamber 20. In some embodiments of the present disclosure, the distance between the joint P2 and the process reaction chamber 20 may be shorter than the distance between the joint P2 and the cooler 221. By such an arrangement, the process gas can be mixed with the cooling gas and cooled as quickly as possible immediately after being discharged from the process reaction chamber 20.

Moreover, the cooling gas supply assembly 23 may include a gas delivery pipe switching element 233 and a one-way valve 235 connected to the cryogenic gas delivery pipeline 230, wherein the gas delivery pipe switching element 233 is located downstream of the cooling gas source 231 and the one-way valve 235 is located downstream of the gas delivery pipe switching element 233. The gas delivery pipe switching element 233 may be configured to selectively control the opening and closing of the cryogenic gas delivery pipeline 230, thereby regulating whether the cooling gas is introduced into the process gas exhaust pipeline 220. The one-way valve 235 may be configured to allow the cooling gas to flow only from the cooling gas source 231 toward the process gas exhaust pipeline 220, and to prevent the process gas or any backflow gas from the process gas exhaust pipeline 220 from flowing back into the cryogenic gas delivery pipeline 230.

In some embodiments of the present disclosure, the semiconductor processing system 1 as shown in FIG. 1 or the semiconductor processing system 2 as shown in FIG. 2 may not include the cooler 121 or 221. Specifically, if the cooling gas supplied by the cooling gas supply assembly 13, 23 to the process gas exhaust pipeline 120, 220 is sufficient to lower the temperature of the process gas discharged from the process reaction chamber 10, 20 to a level that does not cause damage to the pressure control element 127, 227 (and the gas exhaust valve), the use of the cooler 121 or 221 may be omitted. In such embodiments, the cooling gas alone can achieve the necessary cooling effect, and the semiconductor processing system 1, 2 can be configured without the installation of the cooler 121 or 221, thereby simplifying the system design and reducing manufacturing and maintenance costs.

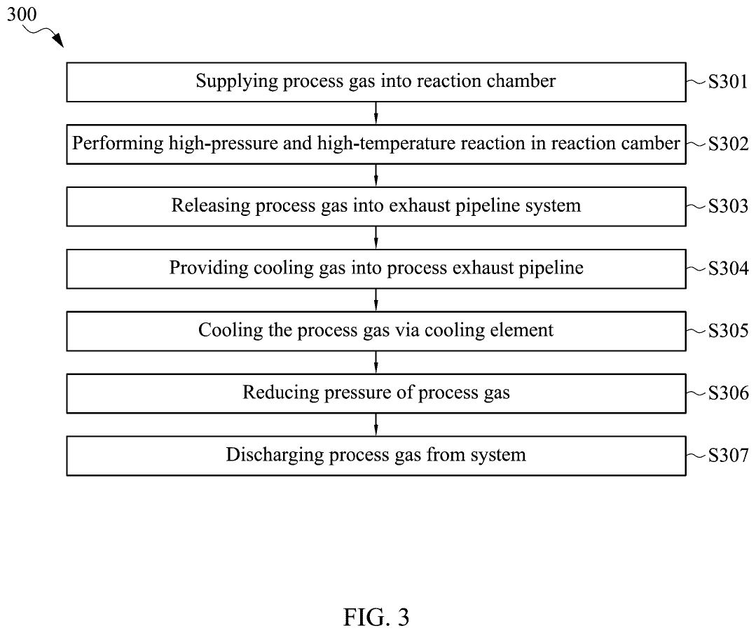

FIG. 3 is a flow chart representing a method 300 for operating the semiconductor processing system 1 or 2 in accordance with an embodiment of the present disclosure.

In step S301, the process gas is supplied from the process gas source 111, 211 into the process reaction chamber 10, 20. In some embodiments of the present disclosure, the process gas may be pressurized (e.g., with booster element 113) prior to entering the process reaction chamber 10, 20.

In step S302, a high-pressure and high-temperature process reaction is performed in the process reaction chamber 10, 20. Because of the reaction, temperature of the process gas rises to a high level and may remain elevated even after the reaction is completed. In some embodiments of the present disclosure, the temperature of the process gas may reach 850° C. and may be held in a thermostatic state during the process reaction. In some embodiments of the present disclosure, the pressure gas of the process gas may be 200 Pa.

In step S303, after the process reaction is finished, the high-temperature process gas may be discharged from the process reaction chamber 10, 20 into the process gas exhaust pipeline 120, 220.

In step 304, the cooling gas source 131, 231 supplies the cooling gas into the process gas exhaust pipeline 120, 220. The cooling gas from the cooling gas source 131, 231 may flow through the cryogenic gas delivery pipeline 130, 230 and can be mixed with the process gas discharged from the process reaction chamber 10, 20 to reduce the temperature of the process gas.

Additionally, a switch (e.g., gas delivery pipe switching element 133) and a valve (e.g., one-way valve 135) can be connected to the cryogenic gas delivery pipeline 130, 230, wherein the switch is located downstream of the cooling gas source 131, 231, and the valve is located downstream of the gas delivery pipe switching element 133.

In order to enable the cooling gas to smoothly flow from the cryogenic gas delivery pipeline 130, 230 into the process gas exhaust pipeline 120, 220 and to effectively mix with the high-temperature process gas within the process gas exhaust pipeline 120, 220 to achieve a temperature reduction effect, the cooling gas may have a temperature substantially lower than 850° C. and down to approximately room temperature (e.g., about 24° C.). In some embodiments, the temperature of the cooling gas falls within any of the ranges disclosed above.

Additionally, the pressure of the cooling gas may be greater than or equal to 200 Pa to ensure sufficient flow momentum for mixing with the high-temperature process gas.

When the cooling gas is a gas different from the process gas (e.g., an inert gas or other gases such as hydrogen (H₂), deuterium (D₂), carbon dioxide (CO₂), nitrogen (N₂), helium (He), or argon (Ar)), mixing the cooling gas with the process gas can also reduce the concentration of the process gas. By diluting the concentration of the process gas during the mixing process, the potential risks associated with the exhaust process can be minimized.

In some embodiments of the present disclosure, the joint P1, P2 between the cryogenic gas delivery pipeline 130, 230 and the process gas exhaust pipeline 120, 220 may be positioned proximate to the process reaction chamber 10, 20. Such an arrangement is intended to enable the process gas, upon being discharged from the process reaction chamber 10, 20 into the process gas exhaust pipeline 120, 220, to be quickly mixed with the cooling gas and cooled. By facilitating an earlier temperature reduction before the process gas reaches the cooler 121, 221, the overall cooling effect can be made more efficient.

In step 305, the process gas flows through the cooler 121, 221, which further reduces the temperature of the process gas. In some embodiments of the present disclosure, the cooler 121, 221 can be connected to a refrigerant source (e.g., inert refrigerant source 122), which supplies refrigerant into the cooler 121, 221. A switch (e.g., switching element 124) may be arranged between the refrigerant source and the cooler 121, 221 to control the flow of the inert refrigerant from the inert refrigerant source into the cooler 121, 221.

In some embodiments of the present disclosure, at least one temperature sensor (e.g., temperature measuring elements 123, 125) can be connected to the process gas exhaust pipeline 120, 220 and positioned adjacent to the cooler 121, 221. For example, two temperature sensors can be located upstream and downstream of the cooler 121, 221, respectively, to measure the temperature changes of the process gas flowing through the cooler 121, 221. The user can adjust the volume of the inert refrigerant and the cooling gas at any time based on the temperature changes measured by the at least one temperature sensor, thereby precisely monitoring and controlling the temperature of the process gas.

In step 306, the process gas flows through the pressure control element 127, 227, which reduces the pressure of the process gas. Since the process gas has been cooled by mixing with the cooling gas, the pressure control element 127, 227 is protected from damage due to high temperatures, thereby extending its lifespan. Moreover, in embodiments where the cooler 121, 221 is employed for secondary cooling of the process gas, the temperature of the process gas may decrease more rapidly, thereby enhancing the cooling efficiency and reducing the overall reaction time. In some embodiments of the present disclosure, the pressure control element 127, 227 includes a gas exhaust valve.

In step 307, after the pressure and temperature of the process gas are reduced, the process gas is discharged out of the semiconductor processing system 1, 2. The discharged process gas may flow into a buffer vessel (e.g., low pressure buffer vessel 128) for safe storage and processing.

In embodiments where the process gas and the cooling gas are of the same type, the process gas is not contaminated by the cooling gas and can therefore be recycled and reused, thereby enhancing economic benefits. For example, the process gas that has been cooled and depressurized in the low pressure buffer vessel 128 may be further directed to a purifier 129, where it undergoes purification. After purification, the process gas can be recovered and reused in subsequent or other semiconductor processing operations.

The following explains the effect of utilizing the cooling gas source 131, 231 and the cooler 121, 221, as described in the present disclosure, on the discharge time of the process gas. Due to the thermal tolerance constraints of the pressure control element 127, 227, it is preferable for the process gas to be cooled to a specific temperature (for example, 200° C.) before passing through the pressure control element 127, 227 to prevent potential damage to the pressure control element 127, 227. Consequently, the temperature of the process gas may affect when gas depressurization can commence using the pressure control element 127, 227 thereby influencing the time of the entire discharge process.

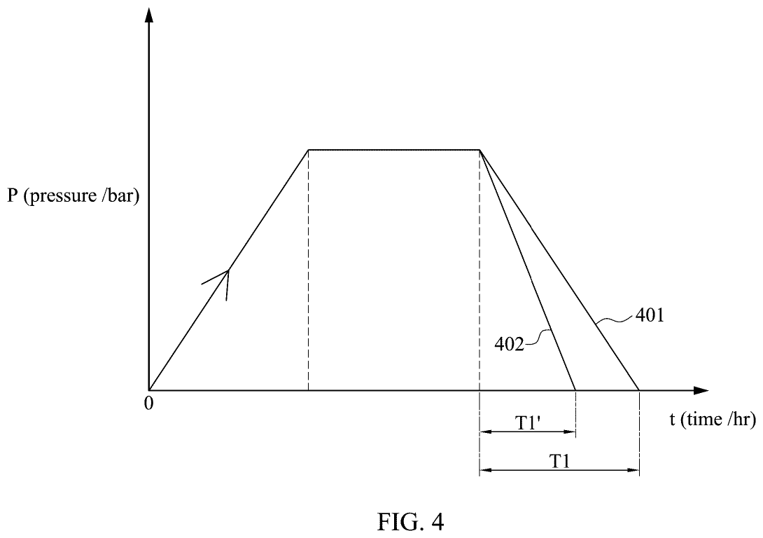

FIG. 4 demonstrates the pressure relief rate when different configurations are utilized, wherein line 401 represents the pressure relief rate when using cooler 121, 221 whereas line 402 represents the pressure relief rate when both the cooler 121, 221 and the cooling gas source 131, 231 are used. As shown in FIG. 4, after the process gas is pressurized, its pressure may remain in a barostatic state for a period. When only the cooler 121, 221 is employed, a longer pressure relief time T1 may be required. In contrast, when both the cooler 121, 221 and the cooling gas source 131, 231 are utilized, the pressure of the process gas may be relieved in a shorter time T1′. Thus, compared to using only the cooler 121, 221, employing both the cooler 121, 221 and the cooling gas source 131, 231 may achieve a faster pressure relief rate.

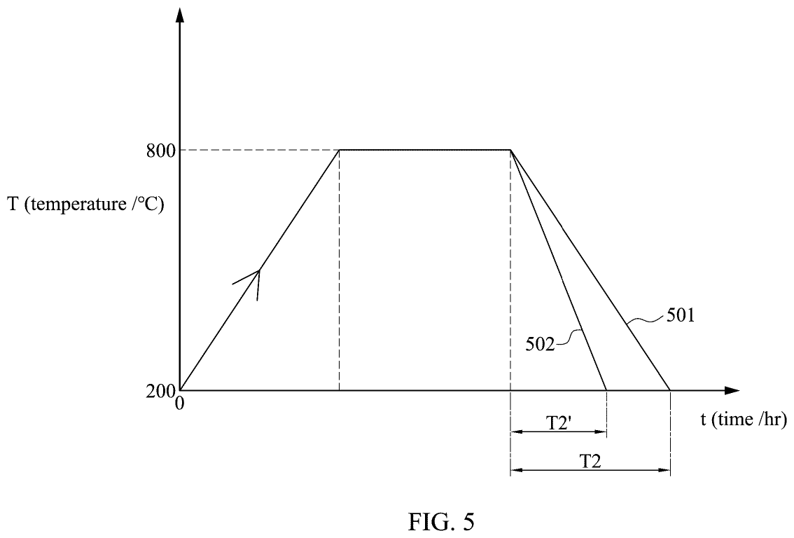

FIG. 5 demonstrates the cooling time required for the process gas when different configurations are utilized, wherein line 501 represents the cooling rate when using cooler 121, 221 whereas line 502 represents the cooling rate when both the cooler 121, 221 and the cooling gas source 131, 231 are used. As described above, it is preferable for the process gas to be cooled below a certain temperature before passing through the pressure control element 127, 227 to prevent damage from high temperatures to the pressure control element 127, 227. Consequently, the cooling efficiency may affect the overall process duration. After the process gas reaches a high temperature due to the process reaction, it may remain in a thermostatic state and begin cooling when the reaction is complete.

As shown in FIG. 5, using only the cooler 121, 221 may result in a longer cooling time T2. Conversely, utilizing both the cooler 121 and the cooling gas source 131 may reduce the cooling time to T2′. This configuration effectively shortens the cooling time, thereby enhancing the efficiency of the gas exhaust process. That is, depressurization of the process gas using the pressure control element 127, 227 may start earlier.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor processing system, comprising:
a process reaction chamber;
a process gas exhaust pipeline connected to the process reaction chamber and configured to expel a process gas from the process reaction chamber; and
a cooling gas source connected to the process gas exhaust pipeline through a cryogenic gas delivery pipeline and configured to supply a cooling gas into the process gas exhaust pipeline via the cryogenic gas delivery pipeline.

2. The semiconductor processing system of claim 1, further comprising a cooler connected to the process gas exhaust pipeline and located downstream of a joint of the process gas exhaust pipeline and the cryogenic gas delivery pipeline.

3. The semiconductor processing system of claim 1, wherein the cooling gas comprises an inert gas.

4. The semiconductor processing system of claim 1, wherein the cooling gas comprises the process gas.

5. The semiconductor processing system of claim 2, wherein a distance between the joint and the process reaction chamber is less than a distance between the joint and the cooler.

6. The semiconductor processing system of claim 5, further comprising a one-way valve connected to the cryogenic gas delivery pipeline and located downstream of the cooling gas source.

7. The semiconductor processing system of claim 2, further comprising a pressure control element connected to the process gas exhaust pipeline and located downstream of the cooler.

8. The semiconductor processing system of claim 2, further comprising a purifier located downstream of the pressure control element.

9. The semiconductor processing system of claim 1, wherein the cooling gas has a temperature ranging from approximately 24° C. to 850° C.

10. The semiconductor processing system of claim 1, wherein the cooling gas has a pressure greater than or equal to 200 Pa.

11. A semiconductor processing system, comprising:
a process reaction chamber comprising
an inner chamber; and
an outer chamber at least partially enclosing the inner chamber;
a process gas exhaust pipeline configured to expel a process gas that undergoes high-temperature and high-pressure reaction in the inner chamber; and
a cooling gas source configured to supply a cooling gas to the process gas exhaust pipeline via a cryogenic gas delivery pipeline, thereby allowing the cooling gas to mix with the process gas expelled from the inner chamber.

12. The semiconductor processing system of claim 11, further comprising a gas exhaust valve configured to reduce a pressure of the process gas that has been mixed with the cooling gas.

13. The semiconductor processing system of claim 11, further comprising a cooler configured to lower a temperature of the process gas expelled from the inner chamber, wherein the cooler is connected to the gas exhaust pipeline and located upstream of the gas exhaust valve.

14. The semiconductor processing system of claim 13, wherein the cooler is configured to receive an inert refrigerant flow from an inert refrigerant source.

15. The semiconductor processing system of claim 13, wherein the cooler is located downstream of a joint of the process gas exhaust pipeline and the cryogenic gas delivery pipeline.

16. The semiconductor processing system of claim 15, wherein a distance between the joint and the process reaction chamber is shorter than a distance between the joint and the cooler.

17. A method of operating a semiconductor processing system, comprising:
discharging a process gas from a process reaction chamber into a process gas exhaust pipeline;
supplying a cooling gas into the process gas exhaust pipeline, wherein a temperature of the cooling gas is lower than a temperature of the process gas and wherein a pressure of the cooling gas is greater than a pressure of the process gas; and
mixing the process gas with the cooling gas in the process gas exhaust pipeline.

18. The method of claim 17, further comprising, after mixing the process gas with the cooling gas, cooling the process gas mixed with the cooling gas via a cooler.

19. The method of claim 17, further comprising: introducing the process gas mixed with the cooling gas to pass through a gas exhaust valve.

20. The method of claim 17, further comprising: purifying and recovering the process gas mixed with the cooling gas, wherein the cooling gas and the process gas are substantially of a same type.
